(19) United States
(12) Patent Application Publication
(10) Pub. No.: US 2012/0112292 A1
(43) Pub. Date: May 10, 2012

(54) INTERMIXED SILICIDE FOR REDUCTION OF EXTERNAL RESISTANCE IN INTEGRATED CIRCUIT DEVICES

(75) Inventors: CHRISTIAN LAVOIE, Pleasantville, NY (US); Ahmet S. Ozcan, Pleasantville, NY (US); Bin Yang, Ossining, NY (US); Zhen Zhang, Ossining, NY (US)

(73) Assignee: INTERNATIONAL BUSINESS MACHINES CORPORATION, ARMONK, NY (US)

(21) Appl. No.: 12/940,394

(22) Filed: Nov. 5, 2010

(51) Int. Cl. H01L 27/118; H01L 21/44

(52) U.S. Cl. 257/408; 438/682; 438/683; 257/E21.476; 257/E27.108

(57) ABSTRACT

A method for forming an alternate conductive path in semiconductor devices includes forming a silicided contact in a source/drain region adjacent to an extension diffusion region and removing sidewall spacers from a gate structure. A metal layer is formed over a portion of the extension diffusion region in a substrate layer to intermix metal from the metal layer with the portion of the extension region without annealing the metal layer. An unmixed portion of the metal layer is removed. The alternate conductive path is formed on the extension diffusion region with intermixed metal by thermal processing after the unmixed portion of the metal layer has been removed.

### BACKGROUND

1. Technical Field

The present invention relates to semiconductor devices and fabrication thereof, and more particularly to methods and devices with reduced external resistance

2. Description of the Related Art

While integrated circuit transistors may take many forms, resistance between such devices and external structures has a significant impact on device performance. High device complexity, different materials, additional material interfaces, etc. all contribute to increasing the external resistance (Rₑₓₜ).

Silicides have been widely used in complementary metal oxide semiconductor (CMOS) devices. Following the scaling trend, devices with P-N junctions are unfortunately more sensitive to defects which cause increased junction leakage and device failures. During annealing processes to form silicides, metal can diffuse preferentially along existing defects or develop local protrusions that extend into (i.e., contact or traverse) junctions (channels). This becomes more severe when junctions become shallower as the devices scaled. The preferential metal diffusion needs to be minimized.

Referring to FIG. 1, a partial cross-sectional view of a transistor device 10 is illustratively shown. The device 10 is formed on a substrate 12. The substrate 12 includes a source/drain (S/D) diffusion region 26 and an extension diffusion region 28, which extends below a gate structure 16 and overlaps a channel region 15.

The gate structure 16 includes a conductor 17, a gate oxide 14 and side spacers 18 (only one side is shown). A silicided junction 30 is formed on or over the S/D region 26 and the extension region 28. The silicided junction 30 connects to a contact 20, which connects to metal lines and other components (not shown). The S/D regions 26 and silicided junctions 30 abut a shallow trench isolation region (STI) 24. Other dielectric layers and materials are employed to encapsulate and isolate contacts 20 and other conductive elements.

FIG. 1 also depicts a resistive circuit 40 from the channel (15) to the contact 20. Circuit 40 includes resistive components (Rₒₗ) for the overlap region of the extension and channel, a resistive component (Rₑₓₜₙ) for the extension region, a resistive component (Rₛₚ) for current going from extension region in the S/D region under the silicide, a resistive component (R_{co}) for the silicided contact/substrate contact resistance 30 and a resistive component (R_{Lumped}) for the via contact 20. These resistive components add in series, e.g., Rₜₒₜₐₗ or Rₑₓₜ=R_{Lumped}+R_{co}+Rₛₚ+Rₑₓₜₙ+Rₒₗ. The resistive components each contribute to Rₑₓₜ in different proportions. In basic terms, the extension (Rₑₓₜₙ) and overlap (Rₒₗ) resistances contribute ˜25% of the Rₑₓₜ, where the extension resistance is about 6-7% of Rₑₓₜ. The extension resistance may be about 500-1500 ohms/square. Contact resistance (R_{co}) can vary from about 10 to 50% of Rₑₓₜ. Devices can suffer from bad link-up between S/D regions 26 and extension region 28.

### SUMMARY

A method includes removing sidewall spacers from a gate structure and forming a metal layer over at least a portion of an extension diffusion region in a substrate layer to intermix metal from the metal layer with the portion of the extension region without annealing the metal layer. The unmixed metal layer is removed. An alternate conductive path is formed on the portion of the extension region with intermixed metal by thermal processing after the unmixed metal layer has been removed. A silicided contact is formed in a source/drain region adjacent to the extension diffusion region.

A method for forming an alternate conductive path in semiconductor devices includes forming a silicided contact in a source/drain region adjacent to an extension diffusion region and removing sidewall spacers from a gate structure. A metal layer is formed over a portion of the extension diffusion region in a substrate layer to intermix metal from the metal layer with the portion of the extension region without annealing the metal layer. An unmixed portion of the metal layer is removed. The alternate conductive path is formed on the extension diffusion region with intermixed metal by thermal processing after the unmixed portion of the metal layer has been removed.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a partial cross-sectional view of a semiconductor device showing resistances of an electrical path between a device channel and a contact via in accordance with the prior art;

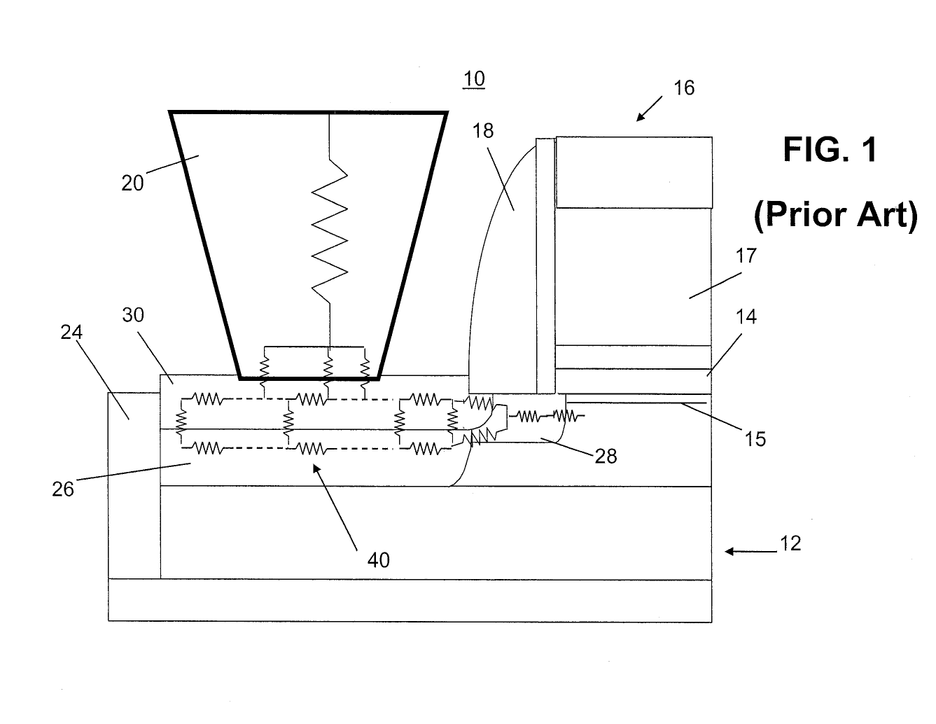

FIG. 2 is a partial cross-sectional view of a semiconductor device showing resistances of an electrical path between a device channel and a contact via having an alternate conductive path in accordance with the present principles;

FIG. 3 is a partial cross-sectional view of a semiconductor device showing a gate structure formed on a substrate;

FIG. 4 is a partial cross-sectional view of a semiconductor device showing source/drain diffusion regions and extension diffusion regions formed for the device of FIG. 3;

FIG. 5 is a partial cross-sectional view of the semiconductor device of FIG. 4 showing silicided contacts formed in accordance with one illustrative embodiment;

FIG. 6 is a partial cross-sectional view of the semiconductor device of FIG. 5 showing silicide layer portions formed to create an alternate conductive path in accordance with one illustrative embodiment;

FIG. 7 is a partial cross-sectional view of the semiconductor device of FIG. 6 with spacers reformed in accordance with one illustrative embodiment;

FIG. 8 is a partial cross-sectional view of a semiconductor device further processed without spacers reformed in accordance with another illustrative embodiment;

FIG. 9 is a plot of sheet resistance (Rs) versus initial metal thickness (nm) for three metal silicides in accordance with one embodiment; and

FIG. 10 is a flow diagram showing an illustrative method for forming an alternate conductive path to reduce external resistance in accordance with one embodiment.

### DETAILED DESCRIPTION OF PREFERRED EMBODIMENTS

In accordance with the present principles, devices and methods are provided to form a thin silicide over a portion of an extension diffusion region to reduce device external resistance. The devices and methods include a metal layer deposited on substrate materials such that the metal layer intermixes with the substrate material (e.g., silicon) to form an intermixed region. An un-intermixed portion of the metal layer is removed from the intermixed region, and the intermixed region is annealed to form a contact on the silicon. The present embodiments may include removing or recessing sidewall spacers from a gate structure (with or without a silicide first being formed on source/drain (S/D) regions) and forming an intermixed silicide layer over a portion of an extension diffusion region.

These embodiments with no or limited metal diffusion produce a box-like silicide profile near the channel region and thus minimize the chance of forming silicided defects. As the metal and semiconductor are mixed in the deposition process, no or limited diffusion takes place during the annealing process. Furthermore, there is no extra metal to diffuse into extension regions and channel regions since the metal above the intermixed layer is etched away before annealing. While in a conventional process (metal deposition plus annealing), there is always extra metal diffusion from other regions, e.g., spacers, during the annealing process. Thus, the devices are prone to the danger of extra metal diffusion along existing defects.

In addition, an alternate conductive path is formed by the intermixed silicide layer in the extension regions. In one embodiment, the alternative conductive path reduces resistance between a contact and a channel (through an extension region). The alternative conductive path may include an ultra-thin silicide formed in the extension region by the intermixing process. The intermixing process may complete silicidation by a thermal budget of further processing. The formation of an intermixed silicide or other mechanism reduces the external resistance and improves device performance.

In one embodiment, an implant into the silicide may be performed to further reduce a silicide to silicon (substrate) contact resistance. Shallow implants such as a cold implant or a Gas Cluster Ion Beam (GCIB) implant may be performed. An additional anneal after implant may be provided at low temperature, e.g., less than 600 degrees C., to diffuse the implanted species to a silicide/substrate interface.

It is to be understood that the present invention will be described in terms of a given illustrative architecture; however, other architectures, structures, substrate materials and process features and steps may be varied within the scope of the present invention. For example, the structure may include a bulk substrate, a semiconductor on insulator substrate, a monocrystalline substrate, etc. In addition, materials disclosed for these structures may have other materials that provide similar functions and/or properties substituted.

Circuits as described herein may be part of a design for an integrated circuit chip. The chip design may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

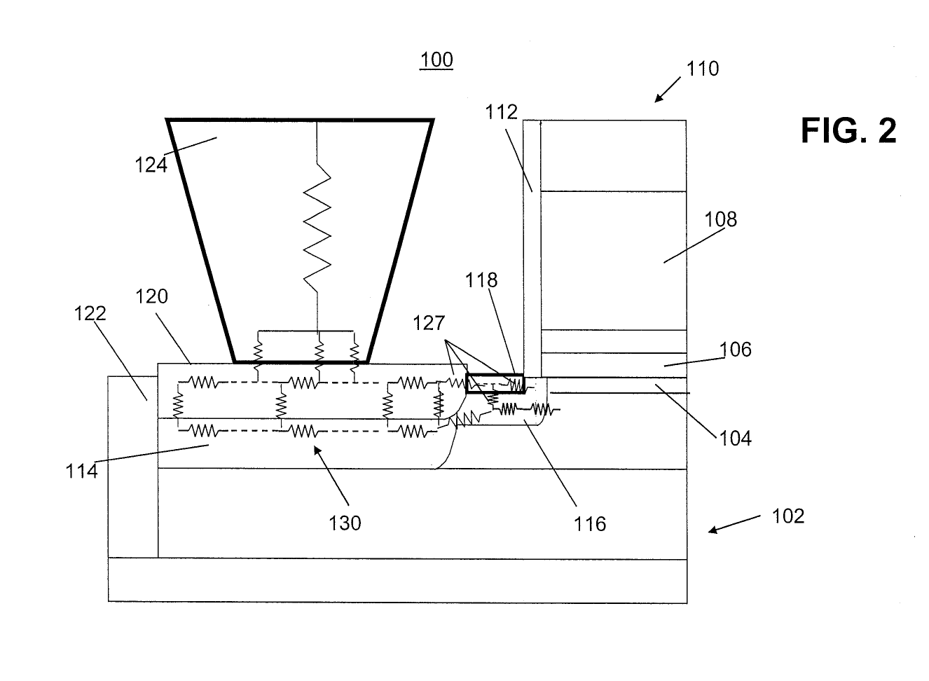

Referring now to the drawings in which like numerals represent the same or similar elements and initially to FIG. 2, a partial cross-sectional view of a transistor device 100 is illustratively shown in accordance with an exemplary embodiment. The device 100 is formed on a substrate 102. The substrate 102 may include a bulk monocrystalline silicon substrate, a silicon on insulator substrate or may include other materials. The substrate 102 includes a source/drain (S/D) diffusion region 114 (a second S/D region is omitted for simplicity). The S/D region 114 is formed by implanting and/or diffusing dopants into the substrate 102. An extension diffusion region 116 also includes dopants implanted and/or diffused into substrate 102 (a second extension region is omitted for simplicity). The extension region 116 extends below a gate structure 110 and overlaps with a channel 104. The gate structure 110 includes a conductor 108, a gate dielectric 106 and side dielectric 112 (only one side is shown, spacers are shown removed).

A silicided junction 120 is formed on or over the S/D region 114 and the extension region 116. The silicided junction 120 connects to a contact 124, which connects to metal lines and other components (not shown). The silicided junction 120 is formed by a silicidation process which reacts metal with silicon. This reaction extends outward from a deposited metal and foams rounded regions in the substrate 220. The S/D regions 114 and silicided junctions 120 abut a shallow trench isolation region (STI) 122. Other dielectric layers and materials are employed to encapsulate and isolate contacts 124 and other conductive elements.

In accordance with one illustrative embodiment, a conductive region 118 is formed to reduce external resistance. In one embodiment, region 118 includes a silicide formed by intermixing a metal in extension region 116. The intermixing process is different from conventional silicide formation processes as will be explained. The silicide region 118 may be ultra-thin, e.g., 1-30 nanometers in thickness. During processing, the silicide region 118 may be formed by reducing a spacer (not shown) to access the underlying extension region 116. The spacer 112 may be restored later, if desired.

FIG. 2 depicts a resistive circuit 130 which connects the channel 104 to the contact 124. Circuit 130 includes a resistive component (Rₒₗ) for the overlap region of the extension (116) and the channel (104), a resistive component (Rₑₓₜₙ) for the extension region 116, a resistive component (R_{co1}) for the silicided contact 120, a resistive component (R_{co2}) for the conductive region 118, and a resistive component (R_{Lumped}) for the via contact 124. The component R_{co2} provides an additional conductive path, which is shown as modified or added resistive elements 127. This conductive region 118 significantly reduces Rₑₓₜ. Since the conductive region 118 provides a more conductive path between the channel 104 and the silicide junction 120 than the extension diffusion 116 alone, a total contact resistance (R_{co}) is significantly reduced. Since R_{co} is a large contributor to Rₑₓₜ, Rₑₓₜ is also significantly reduced.

Forming region 118 by a conventional siliciding process may cause a significant amount of diffusion into the channel region 104. Siliciding often requires that a deposited metal be annealed or heated in place to drive atoms into a matrix (e.g., silicon). With the high concentration of metal and the applied heat, diffusion elements enter and penetrate not only the silicon but other surrounding material, e.g., dielectric materials, etc. In accordance with the present principles, an intermixing process is employed to permit the formation of region 118 with minimal or no diffusion. In this way, the channel region 104 is protected and device performance is improved and not degraded by unwanted metal in the channel region. Furthermore, the intermixed region 118 is box-like in shape since intermixing occurs at or near a surface of the substrate layer 114 and the intermixed metal does not diffuse since it is completely reacted with the substrate 114.

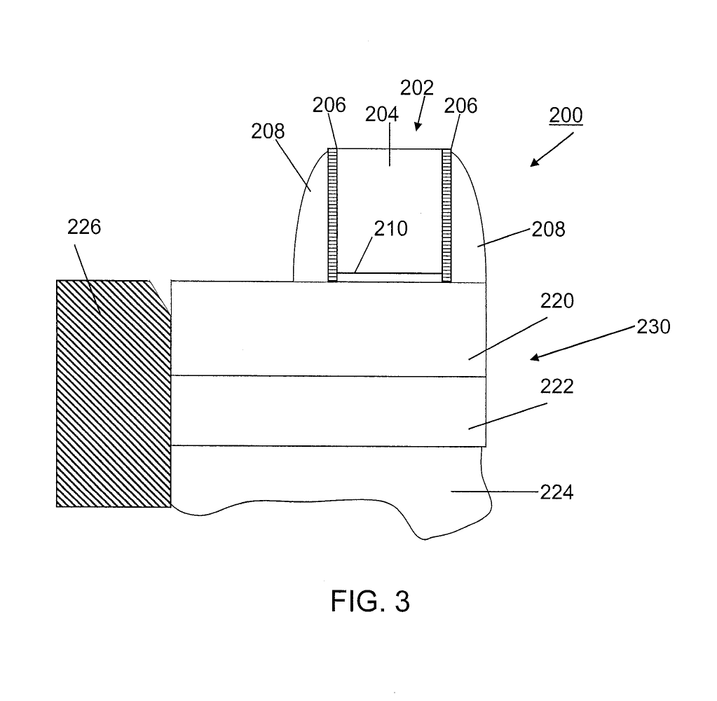

Referring to FIG. 3, a cross-sectional view of a portion of a transistor device 200, e.g., a metal oxide semiconductor field effect transistor (MOSFET) (PFET or NFET), is illustratively depicted to demonstrate the present principles. Device 200 has a gate structure 202 formed on a substrate 230. Gate structure 202 includes a conductor 204 (e.g., a metal or doped polysilicon) formed on a gate dielectric 210 (e.g., gate oxide, such as silicon oxide). The gate conductor 204 includes a dielectric 206 and spacers 208 formed on side-walls thereof. The dielectric 206 may include an oxide such as an oxide of silicon, and spacers 208 may include a nitride of silicon. Other materials may also be employed. The dielectric 206 is optional.

Substrate 230, in this example, includes a semiconductor on insulator structure. Other structures would also benefit from the present principles and may also be employed, e.g., bulk semiconductor substrates, etc. In one embodiment, substrate 230 includes a semiconductor layer 220, which may include materials, such as moncrystalline silicon. A dielectric layer 222 may include an oxide, such as a silicon oxide (buried oxide), and layer 224 also includes a semiconductor material, such as silicon. Shallow trench isolation (STI) regions 226 are formed around the device 200. The STI 226 is depicted on only one side of FIG. 3 for simplicity.

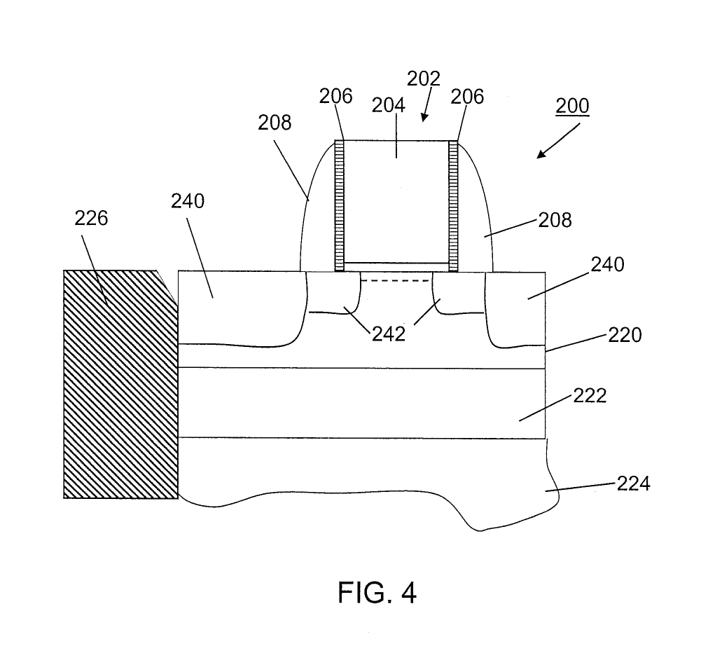

Referring to FIG. 4, source/drain regions 240 and extension regions 242 are formed in accordance with known methods. These diffusion regions 240, 242 may be formed by ion implantation or angled ion implantation methods. The formation of diffusion regions 240, 242 may include masking off portions of the device 200 so that proper dopants types may be provided to selected locations, e.g., masking PFETs so that NFETs can be processed and vice versa. The masking steps may also include masking the gate structures 202, as appropriate. In one embodiment, the structure of FIG. 4 is pre-cleaned, e.g., by washing or etching.

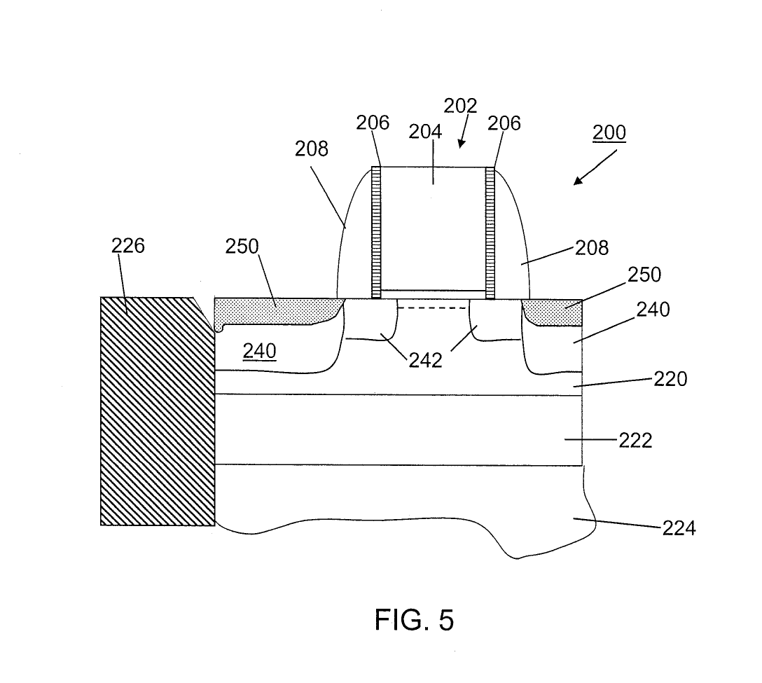

Referring to FIG. 5, the device 200 is further processed to faun silicided contacts 250 in S/D regions 240. In this embodiment, spacers 208 are employed for forming silicided contacts 250. A silicide is first fowled in the S/D regions 240. The silicide is formed by metal deposition and annealing with the metal in place. Silicide contacts 250 (ohmic contacts) are formed in areas where metal is deposited in direct contact with silicon. During annealing, the metal interacts with the silicon to form the silicide. The process is self-aligned. Silicides may include, e.g., Nickel silicide, NiSi; Platinum silicide, PtSi; Titanium silicide, TiSi₂; Tungsten silicide, WSi₂; etc.

The self-aligning aspect of the silicide formation may be employed or the metal layer may be patterned using known methods. An anneal process includes subjecting the device 200 to a temperature of, e.g., between about 200 degrees C. to about 800 degrees C. in an inert environment for between about 1 second to about 30 minutes. These temperatures and times are illustrative and may be altered as needed.

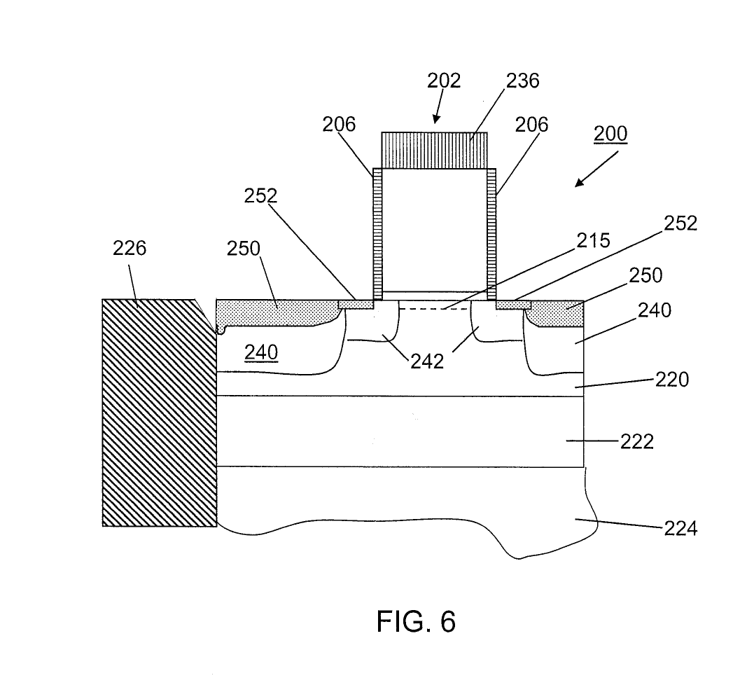

Referring to FIG. 6, the embodiment of FIG. 5 is now processed to add a silicide layer 252 (conductive path). The structure of FIG. 5 is processed by removing the spacers 208 to expose the extension regions 242. An alternate conductive path (252) is created by forming a thin or ultra-tin silicide layer 252. Silicide layer 252 is formed by depositing a metal layer (not shown) over the S/D regions 240 and exposed portions of the extension regions 242. The metal layer is preferably ultra-thin, (e.g., 1 nm-20 nm). The extension regions 242 are exposed by removing (e.g., by etching) the spacer 208 (FIG. 5). Dielectric 206 may remain on the gate structure 202 to protect the sidewalls of the gate structure 202. A mask 236 (e.g., an oxide, nitride of the like) may be deposited and patterned to protect the gate structure 202 as well.

Since silicide layer 252 is preferably thin, an intermixing process is employed to form the silicide in areas where metal is deposited in direct contact with silicon. The metal layer may include one or more of Ni, Pt, Ti, W, Co, rare earth metals (e.g., Er, Yb), Pd, Ir, and their alloys. The metal is first deposited, e.g., by sputtering, chemical vapor deposition, etc. The metal need only be about 1-20 nm in thickness, although a thicker layer may be employed. A thickness of the intermixed layer can be adjusted by using different deposition techniques, e.g., ionized metal plasma (IMP) sputtering and Gas Cluster Ion Beam (GCIB) implantation or changing the deposition conditions, e.g., substrate bias, gas ambient (specie, pressure), etc.

The metal layer is removed by a selective etching process. Any suitable etching process may be performed. It should be noted that the etching process should be at a low temperature (e.g., less than 600 degrees C.) to prevent the diffusion of the metal into substrate layer 220 and especially into the channel region 215.

The metal to silicon contact results in a shallow intermixing of the metal into the silicon of extension region 242 of substrate layer 220. The silicide is preferably completed, after the metal is removed, by annealing the intermixed metal and silicon. The intermixed region 252 is box-like in form and is substantially diffusionless. The intermixed region 252 may include a thickness of less than about 30 nm, and more preferably less than 15 nm. In one embodiment, the molar ratio of metal to silicon is about one, although higher concentrations are possible (e.g., up to about 4). In this way, the metal is encapsulated or fully reacted and further diffusion or metal movement in the substrate layer 220 is thwarted. Since the metal layer is removed, the metal concentration of the metal layer is eliminated as a further source of metal diffusion. In addition, since the metal is removed by etching, the metal is removed from adjacent surfaces (such as dielectric 206), which may otherwise have acted a source of metal for diffusion since some metal may have mixed with these surface as well.

After the metal layer is removed, an anneal may be performed and may include a rapid thermal anneal (RTA), or silicidation can be finished by the thermal budget of subsequent processing steps. The anneal process may include subjecting the device 200 to a temperature of between about 200 degrees C. to about 800 degrees C. in an inert environment for between about 1 second to about 30 minutes. The anneal can also be a fast anneal including a laser anneal and/or a flash anneal. The fast anneals may have a time scale on the order of milliseconds. These temperatures and times are illustrative and may be altered as needed.

The silicide (252) formed by intermixing in this way is diffusionless as conditions are selected to form a highly stable silicide compound that does not easily diffuse into adjoining materials. This reduces the risk of pipe formation in the channel region 215 of the device 200 and other detrimental effects.

The silicide 252 is box-like in form. In general, when a silicide is formed using a rapid thermal anneal right after metal deposition, a radius of curvature of about t/2 is formed at a corner or end of the layer with t being the thickness of the silicide. In accordance with the present principles, with the intermixed process, the radius of curvature is much smaller, e.g., less than about t/4.

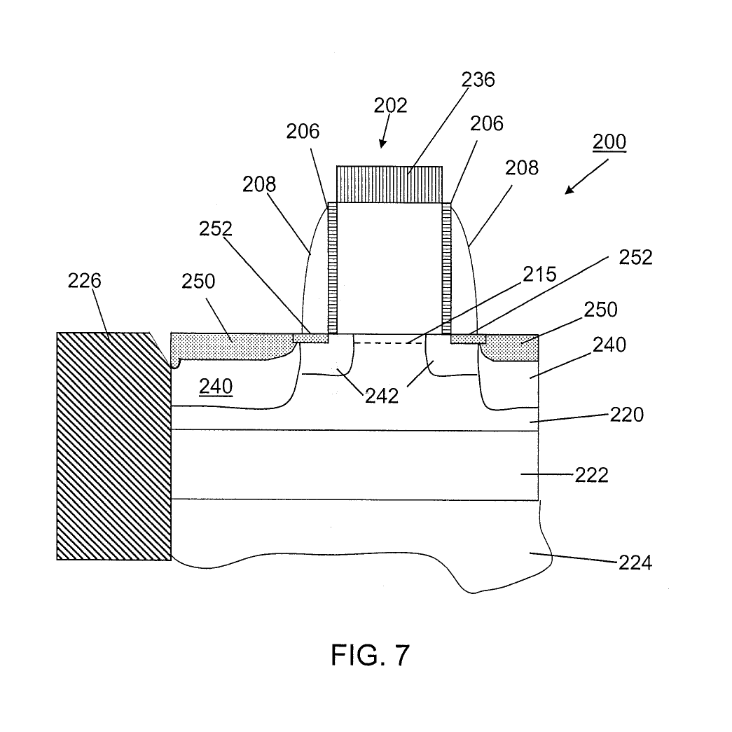

Referring to FIG. 7, after intermixing and/or annealing, an optional implantation step may be employed to further reduce contact resistance between contacts 250, 252 and diffusion regions 240, 242. The implant into silicides 250 and 252 further reduces the silicide to silicon contact resistance. The implant may include a shallow implant such as cold implant or Gas Cluster Ion Beam (GCIB) implant. The GCIB has a beam of high energy nanoscale cluster ions. The clusters are formed when a high pressure gas (approximately 10 atmospheres pressure) expands into a vacuum. The clusters are preferably nano-sized bits of crystalline matter. The clusters are ionized by collisions with energetic electrons. The ionized clusters are accelerated electrostatically to very high velocities, and are focused into a tight beam. A low temperature anneal (e.g., less than 600 degrees C.) may also be employed to drive in the clusters to improve conductivity. Known materials and processes may be employed in this optional implant. The spacer 208 may be reformed or may be omitted from the final structure as desired.

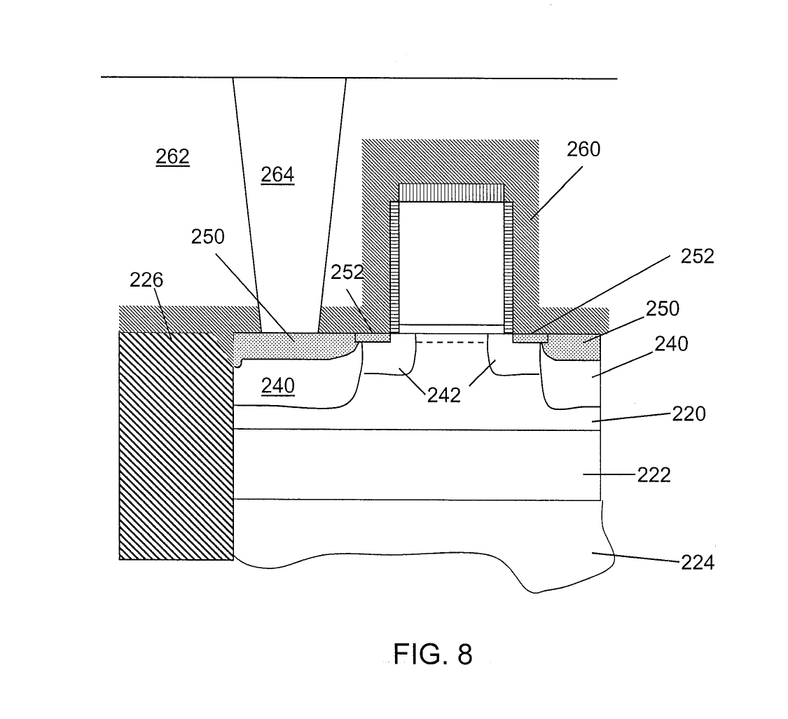

Referring to FIG. 8, processing continues as per a process of record (POR) for a given design. This may include the formation of a dual stress liner 260 or other layers. In addition, contact vias 264 may be formed through dielectric layers 262 to contact the silicided contacts 250 with metal lines (not shown) or other back end of line (BEOL) structures.

In accordance with the present principles, the intermixed silicide layer 252 provides an alternative conductive path designed to reduce external resistance in semiconductor devices. For the silicide layer 252 to be significantly effective at reducing resistance, a plurality of factors needs to be considered. In particularly useful embodiments, properties for thin silicide contacts that need consideration include sheet resistance, composition and phase formation, morphology and thermal stability.

In accordance with the present principles, several silicides have been considered. For example, Nickel silicide (NiSi), Nickel (95%) Platinum (5%) silicide (Ni_{0.95}Pt_{0.05}) and Nickel (90%) Platinum (10%) silicide (Ni_{0.90}Pt_{0.10}) were considered.

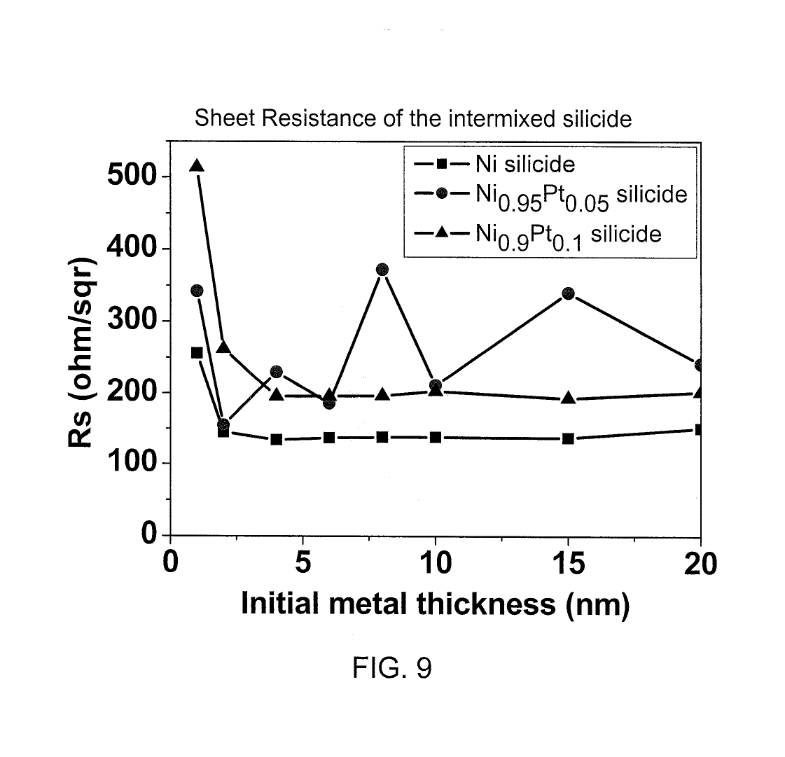

Referring to FIG. 9, sheet resistivity (rho or ρ) in Ohms per square (Ω/#) versus initial metal thickness (deposited) in nm is plotted for each of NiSi, Ni_{0.95}Pt_{0.05} and Ni_{0.90}Pt_{0.10}. The intermixed NiSi was the best, providing a rho of approximately 150-200Ω/# for the desired thickness ranges of the deposited metal (e.g., 2-20 nm).

Similar analysis has been performed to demonstrate high thermal stability for the intermixed silicide materials. With high thermal stability, a lower risk of diffusing conductive materials into a channel region of the device is provided. NiSi is stable (no phase changes, low stable resistance and stable scatter intensity between about 400 and 800 degrees C. Ni_{0.95}Pt_{0.05} is approximately the same with slightly higher resistance and slightly less stability over the same 400 and 800 degrees C. temperature range. Ni_{0.90}Pt_{0.10} is stabile over the temperature range between 400 and 580 degrees C.

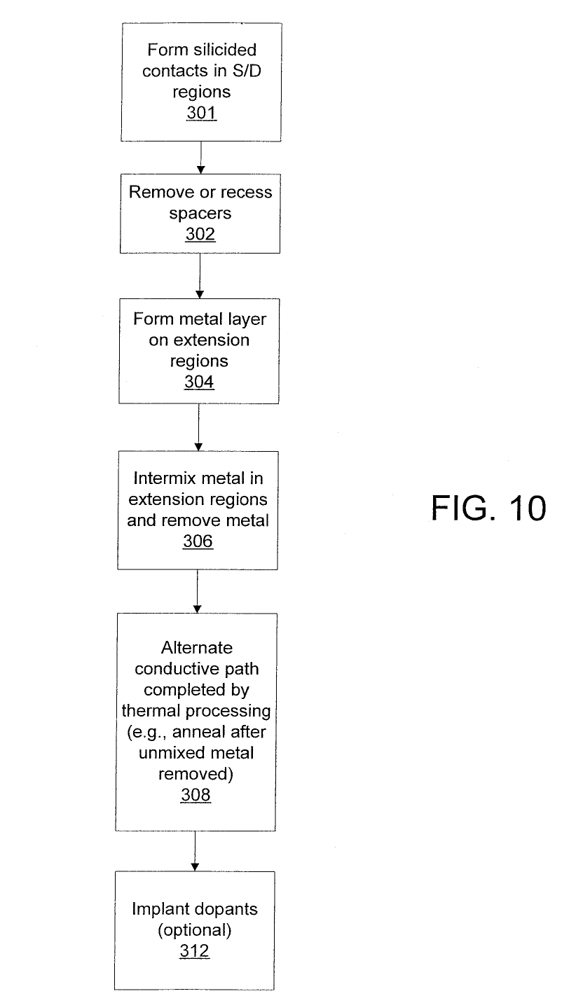

Referring to FIG. 10, a method for reducing external resistance in semiconductor device is illustratively shown. In block 301, a silicided contact is formed in a source/drain region adjacent to an extension diffusion region. In block 302, sidewall spacers are removed from a gate structure. The gate structure is formed on a substrate that has S/D regions and extension regions formed therein. In block 304, a metal layer is formed over at least a portion of an extension diffusion region. The metal layer preferably includes a deposition of one of Ni, Co, Ti, W, Pt, Ir, Pd, and/or a rare earth metal. This includes alloys of these and other metals as well. The metal layer is preferably ultra-thin and is formed a thickness of between about 1 nm to about 20 nm.

In block 306, metal from the metal layer is intermixed with the portion of the extension region. The metal is then removed by selective etching. In block 308, an alternate conductive path is formed by thermal processing of the portion of the extension region with intermixed metal. The thermal processing is performed only after the metal layer has been completely removed. The alternate conductive path provides an additional conductive path to reduce an external resistance of the device formed. The thermal processing may include performing a rapid thermal anneal, or other anneal process or employ a thermal budget of subsequent steps to anneal the extension region with intermixed metal. In block 312, dopants are implanted to further reduce a silicide to silicon contact resistance to reduce an external resistance.

Having described preferred embodiments for reduction of external resistance in integrated circuit devices (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method, comprising:
forming a silicided contact in a source/drain region adjacent to an extension diffusion region;
removing sidewall spacers from a gate structure;
forming a metal layer over at least a portion of the extension diffusion region in a substrate layer to intermix metal from the metal layer with the portion of the extension region without annealing the metal layer;
removing an unmixed portion of the metal layer; and
forming an alternate conductive path on the portion of the extension diffusion region with intermixed metal by thermal processing after the unmixed portion of the metal layer has been removed.

2. The method as recited in claim 1, wherein forming a metal layer includes depositing at least one of Ni, Co, Ti, W, Pt, Ir, Pd, and a rare earth metal.

3. The method as recited in claim 1, wherein the metal layer is ultra-thin and forming a metal layer includes forming a layer having a thickness of between about 2 nm to about 20 nm.

4. The method as recited in claim 1, wherein forming an alternate conductive path includes forming a thickness of the intermixed metal which is controlled by an energy of incoming metal atoms.

5. The method as recited in claim 4, further comprising selecting a deposition technique to control the energy.

6. The method as recited in claim 5, wherein the deposition technique includes one of ionized metal plasma (IMP) sputtering and Gas Cluster Ion Beam (GCIB) implantation.

7. The method as recited in claim 4, wherein the energy is controlled by setting deposition conditions of the metal layer.

8. The method as recited in claim 1, wherein forming an alternate conductive path by thermal processing includes performing an anneal after the unmixed metal is removed.

9. The method as recited in claim 1, wherein forming an alternate conductive path by thermal processing includes employing a thermal budget of subsequent steps to anneal the extension region with intermixed metal.

10. The method as recited in claim 1, wherein the alternate conductive path reduces an external resistance of a device formed by the method.

11. The method as recited in claim 1, further comprising implanting dopants to further reduce a silicide to silicon contact resistance to reduce an external resistance.

12. The method as recited in claim 1, wherein the alternate conductive path includes a stable silicide which is configured so as not to diffuse into a channel region of the substrate layer.

13. A method, comprising:
providing a substrate having source/drain diffusion regions and extension diffusion regions formed therein and a gate structure formed on the substrate;
forming a silicided contact in the source/drain diffusion regions adjacent to the extension diffusion regions;
removing sidewall spacers from the gate structure;
forming a metal layer over at least a portion of the extension diffusion regions in an area vacated by the sidewall spacers to intermix metal from the metal layer with the portion of the extension diffusion regions;
removing the metal layer; and
performing a thermal process to form a silicide layer using intermixed metal in the portion of the extension diffusion regions, the silicide layer forming an alternate conductive path that includes a stable silicide which is configured so as not to diffuse into a channel region of the substrate.

14. The method as recited in claim 13, wherein forming a metal layer includes depositing at least one of Ni, Co, Ti, W, Pt, Ir, Pd, and a rare earth metal.

15. The method as recited in claim 13, wherein the metal layer is ultra-thin and forming a metal layer includes forming a layer having a thickness of between about 2 nm to about 20 nm.

16. The method as recited in claim 13, wherein the alternate conductive path includes a thickness which is controlled by an energy of incoming metal atoms during formation of the metal layer.

17. The method as recited in claim 16, further comprising selecting a deposition technique to control the energy wherein the energy is controlled by setting deposition conditions of the metal layer.

18. The method as recited in claim 17, wherein the deposition technique includes one of ionized metal plasma (IMP) sputtering and Gas Cluster Ion Beam (GCIB) implantation.

19. The method as recited in claim 13, wherein the alternate conductive path is formed by thermal processing which includes performing an anneal after the unmixed metal is removed.

20. The method as recited in claim 13, wherein the alternate conductive path is formed by thermal processing which includes employing a thermal budget of subsequent steps to anneal the extension region with intermixed metal.

21. The method as recited in claim 13, further comprising implanting dopants to further reduce a silicide to silicon contact resistance to reduce an external resistance.

22. The method as recited in claim 13, wherein the alternate conductive path includes a stable silicide which is configured so as not to diffuse into a channel region of the substrate.

23. A semiconductor device, comprising:
a substrate having a gate structure formed thereon and including source/drain diffusion regions and extension diffusion regions connected to the source/drain diffusion regions;
silicided contacts formed on the source/drain diffusion regions; and
silicide layer portions formed on at least a portion of the extension diffusion regions, the silicide layer portions being coupled to the silicided contacts to reduce contact resistance between the extension diffusion regions and the silicided contacts to reduce an external resistance of the device, the silicide layer including a box-like profile having a radius of curvature less than t/4 with t being a thickness of the silicide layer portions.

24. The device as recited in claim 23, wherein the silicide layer portions include a stable phase of at least one of Ni, Co, Ti, W, Pt, Ir, Pd, and a rare earth metal.

25. The device as recited in claim 19, wherein the metal layer is ultra-thin and having a thickness of between about 2 nm to about 20 nm.
